(19) United States
(12) Patent Application Publication
(10) Pub. No.: US 2024/0365504 A1
(43) Pub. Date: Oct. 31, 2024

(54) COOLING DEVICE

(71) Applicant: BITMAIN TECHNOLOGIES INC., Beijing (CN)

(72) Inventors: Zesen NIE, Beijing (CN); Hongshan ZHU, Beijing (CN); Shaoming HUANG, Beijing (CN); Wenkai CUI, Beijing (CN)

(21) Appl. No.: 18/649,888

(22) Filed: Apr. 29, 2024

(30) Foreign Application Priority Data
Apr. 28, 2023 (CN) 202321021396.9

(51) Int. Cl. H05K 7/20

(52) U.S. Cl. CPC H05K 7/20254

(57) ABSTRACT

The present application provides a cooling device. The cooling device includes a first plate and a second plate. A first surface of the first plate is provided with a runner. The runner is configured for accommodating a fluid. The runner has a zigzag shape. The first surface of the first plate is in contact with the second plate. The cooling device of the present application has an enhanced heat dissipation performance.

### CROSS-REFERENCE TO RELATED APPLICATION

This application claims priority to Chinese Patent Application No. 202321021396.9, filed on Apr. 28, 2023, which is hereby incorporated by reference in its entirety.

### TECHNICAL FIELD

The present application relates to, but is not limited to, the field of cooling devices, and specifically relates to a cooling device.

### BACKGROUND

A cooling device achieves heat dissipation of a heating device through heat exchange between an internally-flowing fluid and the heating device. A goal pursued by those skilled in the art is to continuously enhance the heat dissipation effect of the cooling device.

In view of this, a problem of the present application is how to enhance the heat dissipation effect of the cooling device.

### SUMMARY

The present application provides a cooling device, having an enhanced heat dissipation effect.

The present application provides a cooling device. The cooling device includes a first plate and a second plate. A first surface of the first plate is provided with a runner. The runner is configured for accommodating a fluid and has a zigzag shape. The first surface of the first plate is in contact with the second plate.

Here, the runner is provided to have a zigzag shape, so that the runner may have various arrangements. This is beneficial to increase the area of an overlapping portion between the runner and the heating device, and further promote the heat exchange between the fluid and the heating device, so that the cooling device has a stronger heat dissipation effect.

In some possible embodiments, the first plate and the second plate are molded by cast-molding.

In this embodiment, the first plate and the second plate are made by cast-molding. Since all the runners can be formed by cast-molding in one-time casting process, the manufacturing time of the cooling device is greatly shortened. Further, the cast-molding of the first plate and the second plate only needs to use specific molds, thereby reducing the processing cost of the cooling device. Furthermore, by using different molds, different runners can be obtained in the cooling device, so that various arrangements of the runner can be easily achieved.

In some possible embodiments, the first plate and the second plate are integrated by brazing.

In this embodiment, the first plate and the second plate are integrated by brazing, thereby achieving the assembling of the first plate and the second plate. In this way, the use of brazing processing improves the assembling speed of the first plate and the second plate, and further shortens the manufacturing time of the cooling device.

In some possible embodiments, the runner may include a plurality of straight segments and a plurality of bent segments. The plurality of straight segments are arranged in parallel. The plurality of straight segments are communicated head to tail through the plurality of bent segments.

In this embodiment, since the plurality of straight segments of the runner are arranged in parallel and communicated with each other head to tail, the arrangement of the runner on the first plate can be denser, which makes the area of the overlapping portion between the runner and the heating device larger, further accelerates the heat exchange between the fluid and the heating device, and enhances the heat dissipation effect of the cooling device.

In some possible embodiments, a guide strip may be disposed at a bent segment of the runner. An extending direction of the guide strip is substantially consistent with an extending direction of the runner.

In this embodiment, the guide strip arranged at the bent segment of the runner has substantially the same extending direction as that of the runner, so the fluid in the runner can be guided to flow along the extending direction of the runner. In this way, the flow resistance of the fluid at the bent segment of the runner is significantly reduced, thereby promoting the flow of the fluid in the runner.

In some possible embodiments, an end portion of the runner may be provided with an inlet-and-outlet port. The inlet-and-outlet port is configured for the fluid to flow into and out of the runner. The inlet-and-outlet port is in communication with the runner at an obtuse angle.

In this embodiment, by arranging the inlet-and-outlet port to be in communication with the runner at the obtuse angle, the flow resistance of the fluid at the inlet-and-outlet port is reduced, thereby promoting the flow of the fluid in the runner.

In some possible embodiments, a side surface of the runner may be provided with a micro-rib structure.

In this embodiment, the micro-rib structure arranged on the side surface of the runner can disturb the fluid flowing in the runner. Such disturbance can promote the heat exchange between the fluid and the heating device, so that the cooling device has a stronger heat dissipation effect.

In some possible embodiments, the first plate may be provided with a first mounting hole. The first mounting hole is configured for installing a heating device.

The micro-rib structure is arranged around the first mounting hole.

In this embodiment, the micro-rib structure is arranged around the first mounting hole. Since the micro-rib structure is arranged on the side surface of the runner, the micro-rib structure increases the thickness of the wall of the runner around the first mounting hole, compensates the cavity in the wall caused by the first mounting hole, and ensures the thickness and sealing performance of the wall.

It should be understood that the foregoing general description and the following detailed description are only exemplary and explanatory, and do not limit the present application.

### BRIEF DESCRIPTION OF DRAWINGS

The accompanying drawings, which are incorporated herein and constitute a part of the specification, illustrate embodiments that are consistent with the present application; and together with the specification, serve to explain the principles of the present application.

FIG. 1A is an exploded view of a cooling device in an embodiment of the present application.

FIG. 1B is a top view of a first plate of the cooling device in FIG. 1A.

FIG. 1C is a top view of a second plate of the cooling device in FIG. 1A.

FIG. 2A is a schematic diagram of a first example of a cross-sectional shape of a runner in a first plate in an embodiment of the present application.

FIG. 2B is a schematic diagram of a second example of the cross-sectional shape of the runner in the first plate in an embodiment of the present application.

FIG. 2C is a schematic diagram of a third example of the cross-sectional shape of the runner in the first plate in an embodiment of the present application.

FIG. 2D is a schematic diagram of a fourth example of the cross-sectional shape of the runner in the first plate in an embodiment of the present application.

FIG. 3A is a schematic diagram of a first example of an arrangement of a runner in a first plate in an embodiment of the present application.

FIG. 3B is a schematic diagram of a second example of an arrangement of the runner in the first plate in an embodiment of the present application.

FIG. 3C is a schematic diagram of a third example of an arrangement of the runner in the first plate in an embodiment of the present application.

FIG. 4A is a schematic diagram of a first example of a cross-sectional shape of a guide strip disposed in a runner in an embodiment of the present application.

FIG. 4B is a schematic diagram of a second example of the cross-sectional shape of the guide strip disposed in the runner in an embodiment of the present application.

FIG. 4C is a schematic diagram of a third example of the cross-sectional shape of the guide strip disposed in the runner in an embodiment of the present application.

FIG. 5A is a schematic diagram of a first example of an arrangement of a guide strip disposed in a runner in an embodiment of the present application.

FIG. 5B is a schematic diagram of a second example of an arrangement of the guide strip disposed in the runner in an embodiment of the present application.

FIG. 5C is a schematic diagram of a third example of an arrangement of the guide strip disposed in the runner in an embodiment of the present application.

FIG. 5D is a schematic diagram of a fourth example of an arrangement of the guide strip disposed in the runner in an embodiment of the present application.

FIG. 6 is a cross-sectional view of an obtuse-angle communicating part between the runner and an inlet-and-outlet port in an embodiment of the present application.

FIG. 7A is a schematic diagram of a first example of an arrangement of a micro-rib structure in a runner in an embodiment of the present application.

FIG. 7B is a schematic diagram of a second example of an arrangement of the micro-rib structure in the runner in an embodiment of the present application.

FIG. 7C is a schematic diagram of a third example of an arrangement of the micro-rib structure in the runner in an embodiment of the present application.

FIG. 8A is a schematic diagram of a first example of a micro-rib structure in an embodiment of the present application.

FIG. 8B is a schematic diagram of a second example of the micro-rib structure in an embodiment of the present application.

FIG. 8C is a schematic diagram of a third example of the micro-rib structure in an embodiment of the present application.

FIG. 9 is a perspective view of an example the micro-rib structure in an embodiment of the present application, the micro-rib structure being arranged around the first mounting hole.

### DESCRIPTION OF THE REFERENCE NUMBERS

1—cooling device; 10—first plate; 20—second plate; 11—runner; 12—guide strip; 13—inlet-and-outlet port; 14—micro-rib structure; 15—first mounting hole; 21—second mounting hole; 111—side surface; 112—bottom surface; α—base angle; 11A—straight segment; 11B—bent segment; 11C—connecting segment; 113—wall; 13A—uniform segment; 13B—transition segment; β—transition angle; H—first height; h—second height.

### DESCRIPTION OF EMBODIMENTS

In the following description, for the purpose of explanation rather than limitation, specific details such as structures, devices and technologies are set forth in order to thoroughly understand the embodiments of the present application. However, it should be clear to those skilled in the art that the technical solutions of the present application may also be implemented in other embodiments without these specific details. In other cases, detailed descriptions of well-known structures, devices and methods are omitted so as to avoid unnecessary details that may hinder the description of embodiments of the present application.

The embodiments of the present application provide a cooling device. The cooling device may be used for heat dissipation (or cooling) of a heating device. In some scenarios, the heating device may be an electronic device. For example, the electronic device may be a central processing unit (CPU), a graphics processing unit (GPU), a digital signal processor (DSP), or other integrated circuit chips. In some scenarios, the heating device may also be an electrical apparatus. For example, the electrical apparatus may be a power module or other electrical apparatus. It should be understood that the heating device may be any equipment, device or apparatus capable of emitting heat, which is not specifically limited by the embodiments of the present application.

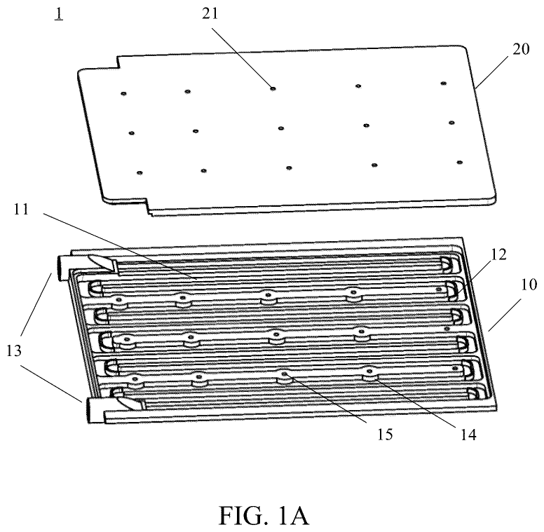

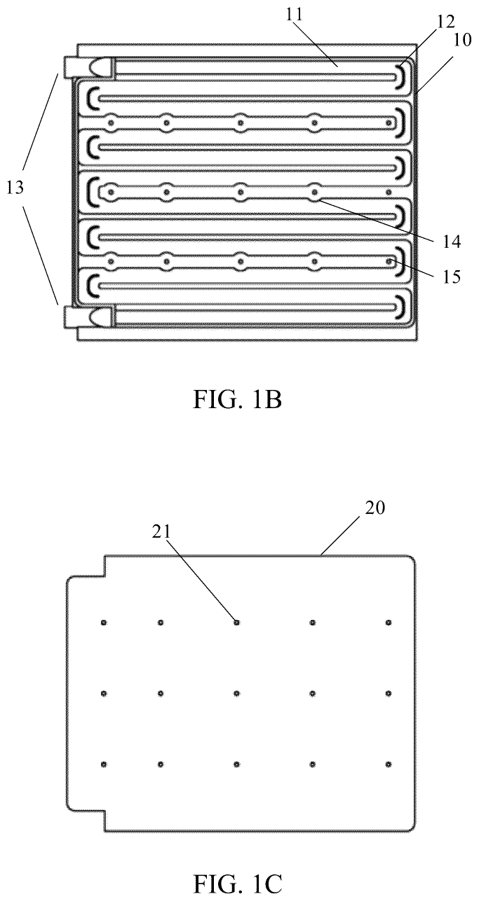

FIG. 1A to FIG. 1C are schematic diagrams of a cooling device in an embodiment of the present application. As shown in FIG. 1A to FIG. 1C, the cooling device 1 includes a first plate 10 and a second plate 20. A first surface of the first plate 10 is provided with a runner 11. The runner 11 is configured for accommodating a fluid. The runner 11 has a zigzag shape. The first surface of the first plate 10 is in contact with the second plate 20.

In the present embodiment, the runner 11 is configured to have a zigzag shape, thus the runner 11 may have various arrangements. This is beneficial to increase the area of the overlapping portion between the runner 11 and the heating device, and further promote the heat exchange between the fluid and the heating device, so that the cooling device 1 has a stronger heat dissipation effect.

In FIG. 1A, the first surface of the first plate 10 is upward and a second surface of the first plate 10 is downward. A first surface of the second plate 20 is downward and a second surface of the second plate 20 is upward.

The runner 11 is disposed in the first surface of the first plate 10. In other words, the runner 11 is a channel for the fluid to flow, which is disposed in the first surface of the first plate 10.

In an embodiment of the present application, since the runner 11 is bent, the runner 11 may have various arrangements on the first surface of the first plate 10. This is beneficial to increase the area of the overlapping portion between the runner 11 and the heating device, and further promote the heat exchange between the fluid and the heating device, so that the cooling device 1 has a stronger heat dissipation effect.

The first plate 10 and the second plate 20 are assembled together. In an embodiment, the first plate 10 and the second plate 20 may be molded by cast-molding. Because the first surface of the first plate 10 is provided with the runner 11, the runner 11 of the first plate 10 needs to be taken into account in the development of a mold used in the cast-molding. In an example, the first plate 10 and the second plate 20 may be molded by die-casting. It should be understood that the first plate 10 and the second plate 20 may also be manufactured by other cast-molding processes, and may also be manufactured by other process than cast-molding, which is not specifically limited in the embodiments of the present application.

Here, the first plate 10 and the second plate 20 are molded by cast-molding. Since the cast-molding can form all the runners 11 in one-time casting process, the manufacturing time of the cooling device 1 is greatly shortened. Further, the cast-molding of the first plate 10 and the second plate 20 only needs to use specific molds, thereby reducing the processing cost of the cooling device 1. In addition, by using different molds, different runners 11 can be obtained in the cooling device 1, so that various arrangements of the runner can be easily achieved.

In an embodiment, the first plate 10 and the second plate 20 are integrated by brazing. The first surface of the first plate 10 is in contact with the first surface of the second plate 20. In an embodiment, the first plate 10 and the second plate 20 may be integrated by tunnel brazing. Specifically, firstly, materials such as brazing paste and flux are added to the contact areas of the first surface of the first plate 10 and the first surface of the second plate 20. Then, the first plate 10 and the second plate 20 are pressed together by using a smelting tool. The pressed first plate 10 and the second plate 20 are sent to a tunnel brazing furnace for welding. Here, the first plate 10 and the second plate 20 are integrated by brazing, thereby achieving the assembling of the first plate 10 and the second plate 20. In this way, the use of brazing processing improves the assembling speed of the first plate 10 and the second plate 20, and further shortens the manufacturing time of the cooling device 1. It should be understood that the first plate 10 and the second plate 20 may also be connected by other welding methods such as arc welding, laser beam welding and electric resistance welding, or may be connected by other methods such as bolt fixing and snap-fit fixing, which is not specifically limited in the embodiments of the present application.

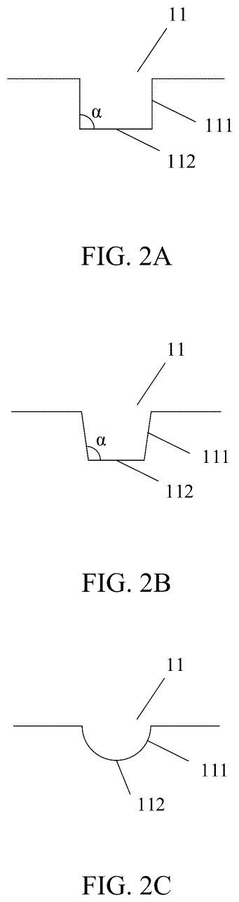

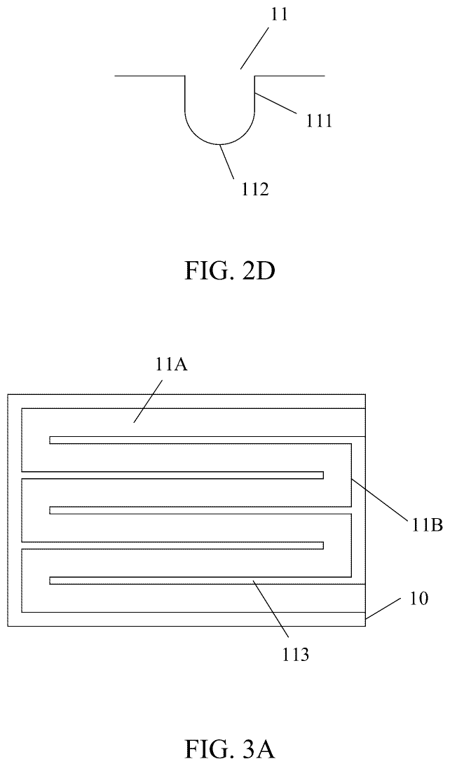

The runner 11 may have various cross-sectional shapes. The cross-sectional shape of the runner 11 is defined by a side surface and a bottom surface of the runner 11. FIG. 2A to FIG. 2D are schematic diagrams of several examples of cross-sectional shapes of runners in embodiments of the present application.

In an example, as shown in FIG. 2A, the cross-sectional shape of the runner 11 may be rectangular, and the base angle α formed by the side surface 111 and the bottom surface 112 of the runner 11 may be a right angle. In some cases, the cross-sectional shape of the runner 11 may be square. In some cases, the base angle α of the runner 11 may be a rounded corner.

In an example, as shown in FIG. 2B, the cross-sectional shape of the runner 11 may be trapezoidal, and the base angle α formed by the side surface 111 and the bottom surface 112 of the runner 11 may be an obtuse angle. In some cases, the cross-sectional shape of the runner 11 may be of an isosceles trapezoid. In some cases, the cross-sectional shape of the runner 11 may be of a right-angled trapezoid. In this case, one base angle α of the runner 11 may be a right angle. In some cases, the base angle α of the runner 11 may be a rounded corner.

In an example, as shown in FIG. 2C, the cross-sectional shape of the runner 11 may be semicircular. In this case, both the side surface 111 and the bottom surface 112 of the runner 11 are a part of an arc.

In an example, as shown in FIG. 2D, the cross-sectional shape of the runner 11 may be of a combination of a rectangle and a semicircle. In this case, the side surface 111 of the runner 11 may define a rectangular portion, and the bottom surface 112 may define a semicircular portion.

It should be understood that the cross-sectional shape of the runner 11 may be of any combination of the above shapes, or the runner 11 may also have other cross-sectional shapes, which is not specifically limited in the embodiments of the present application.

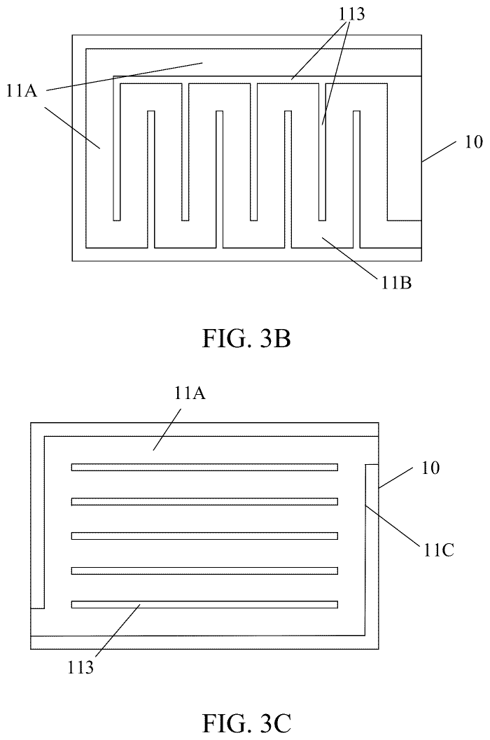

The runner 11 may also have various arrangements. FIG. 3A to FIG. 3C are schematic diagrams of several examples of the arrangement of the runner in the embodiments of the present application.

In an example, as shown in FIG. 3A, the runner 11 may include a plurality of straight segments 11A and a plurality of bent segments 11B. The plurality of straight segments 11A are arranged in parallel. The plurality of straight segments 11A are communicated with each other head to tail through the plurality of bent segments 11B. In this way, the fluid in the runner 11 flows through the plurality of straight segments 11A in sequence.

In an example, as shown in FIG. 3B, the runner 11 may include a plurality of straight segments 11A and a plurality of bent segments 11B. Some straight segments 11A of the plurality of straight segments 11A are arranged in parallel. The plurality of straight segments 11A are communicated with each other head to tail through the plurality of bent segments 11B. In this way, the fluid in the runner 11 flows through the plurality of straight segments 11A in sequence.

In an example, as shown in FIG. 3C, the runner 11 may include a plurality of straight segments 11A and two connecting segments 11C. The plurality of straight segments 11A are arranged in parallel. The end portions of the plurality of straight segments 11A located on the same side thereof are communicated with each other by one connecting segment 11C. The end portions of the plurality of straight segments 11A located on the other side thereof are communicated with each other by the other connecting segment 11C. In this way, the fluid in the runner 11 flows in parallel through the plurality of straight segments 11A.

It should be understood that the runner 11 may also take other arrangements, which is not specifically limited by the embodiments of the present application. Further, the bending angle of the bent segment 11B may be set as required. For example, in FIG. 3A, the bending angle of the bent segment 11B may be 180 degrees. For another example, in FIG. 3B, the bending angles of the bent segment 11B may be 90 degrees and 180 degrees.

With continued reference to FIG. 3A to FIG. 3C, in order to form the bent runner 11, the portions of each segment of the runner 11 (including the straight segment 11A, the bent segment 11B, and the connecting segment 11C) except the communicating portion may be separated by a wall 113. The wall 113 may be flush with the first surface of the first plate 10, and in contact with the first surface of the second plate 20. On the one hand, the wall 113 is fixed to the first surface of the second plate 20 by brazing, so as to achieve the fixed connection between the first plate 10 and the second plate 20. On the other hand, the contact between the wall 113 and the first surface of the second plate 20 is sealed, so as to ensure that the fluid only flows in the runner 11.

Since the runner 11 includes the plurality of straight segments 11A arranged in parallel, the arrangement of the runner 11 on the first plate 10 can be denser, which makes the area of the overlapping portion between the runner 11 and the heating device larger, further accelerates the heat exchange between the fluid and the heating device, and enhances the heat dissipation effect of the cooling device 1. Furthermore, the plurality of straight segments 11A may be communicated with each other head to tail, which reduces the flow resistance of the fluid in the runner 11, and further enhances the heat dissipation effect of the cooling device 1.

In an embodiment, a guide strip 12 may be disposed at the bent segment 11B of the runner 11. An extending direction of the guide strip 12 is generally consistent with an extending direction of the runner 11. The guide strip 12 may be disposed on the bottom surface 112 of the runner 11. The shape, size and number of the guide strip 12 may be set according to actual requirements.

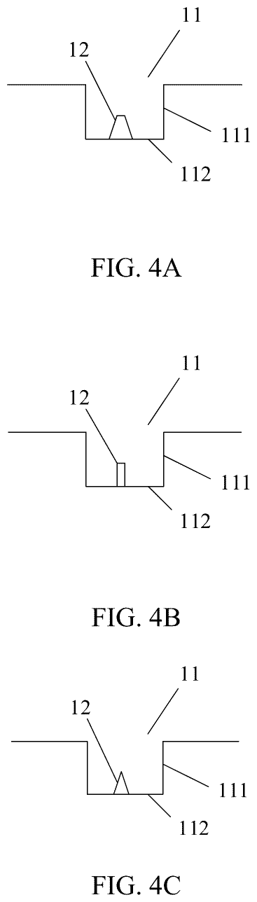

The guide strip 12 may have various cross-sectional shapes. FIG. 4A to FIG. 4C are schematic diagrams of several examples of cross-sectional shapes of the guide strip arranged in the runner in the embodiments of the present application.

In an example, as shown in FIG. 4A, the cross-sectional shape of the guide strip 12 may be trapezoidal.

In an example, as shown in FIG. 4B, the cross-sectional shape of the guide strip 12 may be rectangular.

In an example, as shown in FIG. 4C, the cross-sectional shape of the guide strip 12 may be triangular.

It should be understood that the cross-sectional shape of the guide strip 12 may be of any combination of the above shapes, or the guide strip 12 may also have other cross-sectional shapes, which is not specifically limited in the embodiments of the present application.

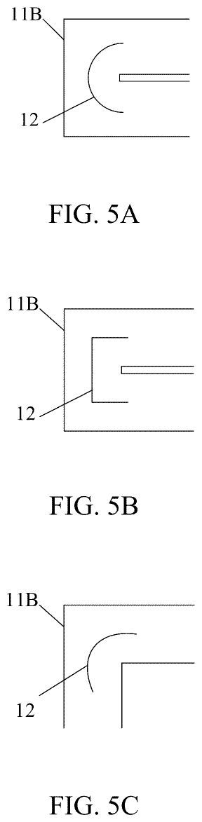

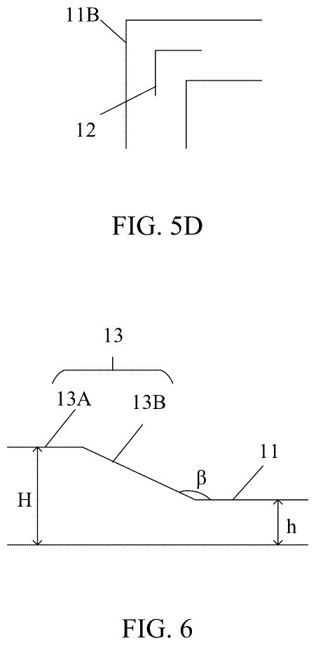

The guide strip 12 may have various arrangements. FIG. 5A to FIG. 5D are schematic diagrams of several examples of the arrangement of the guide strip arranged in the runner in the embodiments of the present application.

In an example, as shown in FIG. 5A, the bending angle of the bent segment 11B is 180 degrees, and the guide strip 12 is arc-shaped and generally extends along the extending direction of the bent segment 11B.

In an example, as shown in FIG. 5B, the bending angle of the bent segment 11B is 180 degrees, and the guide strip 12 is C-shaped and generally extends along the extending direction of the bent segment 11B.

In an example, as shown in FIG. 5C, the bending angle of the bent segment 11B is 90 degrees, and the guide strip 12 is arc-shaped and generally extends along the extending direction of the bent segment 11B.

In an example, as shown in FIG. 5D, the bending angle of the bent segment 11B is 90 degrees, and the guide strip 12 is L-shaped and generally extends along the extending direction of the bent segment 11B.

It should be understood that the guide strip 12 may also take other arrangements, which is not specifically limited in the embodiments of the present application.

In an example, a plurality of guide strips 12 may be arranged at the bent segment 11B. The plurality of guide strips 12 may be arranged in parallel.

In an embodiment of the present application, the guide strip 12 arranged at the bent segment 11B of the runner 11 has generally the same extending direction as that of the runner 11, so the fluid in the runner 11 can be guided to flow along the extending direction of the runner 11. In this way, the flow resistance of the fluid at the bent segment 11B of the runner 11 is significantly reduced, thereby promoting the flow of the fluid in the runner 11.

In an embodiment, an end portion of the runner 11 may be provided with an inlet-and-outlet port 13. The inlet-and-outlet port 13 is configured for the fluid to flow into and out of the runner 11. The inlet-and-outlet port 13 is in communication with the runner 11 at an obtuse angle.

The inlet-and-outlet port 13 is tubular and may have various cross-sectional shapes. For example, the cross-sectional shape of the inlet-and-outlet port 13 may be rectangular, square, circular, elliptical, trapezoidal or other shapes.

FIG. 6 is a cross-sectional view of an obtuse-angle communicating part between the runner and the inlet-and-outlet port in the embodiment of the present application. As shown in FIG. 6, the inlet-and-outlet port 13 may include a uniform segment 13A and a transition segment 13B. The uniform segment 13A has a first height H. The first height H of the uniform segment 13A is greater than a second height h of the runner 11. The height of the transition segment 13B changes from the first height H of the uniform segment 13A to the second height h of the runner 11.

In an embodiment, as shown in FIG. 6, the uniform segment 13A, the transition segment 13B and the runner 11 may be connected in a bending manner. In an embodiment, the uniform segment 13A, the transition segment 13B and the runner 11 may be smoothly connected to each other.

It should be seen that a transition angle β formed by a top surface of the transition segment 13B and the runner 11 is an obtuse angle. Therefore, the inlet-and-outlet port 13 and the runner 11 are considered to be communicated at the obtuse angle.

In the embodiment of the present application, by arranging the inlet-and-outlet port 13 to be in communication with the runner 11 at the obtuse angle, the flow resistance of the fluid at the inlet-and-outlet port 13 is reduced, thereby promoting the flow of the fluid in the runner 11.

In an embodiment, a side surface of the runner 11 may be provided with a micro-rib structure 14. Specifically, the micro-rib structure 14 is a convex portion disposed on the side surface of the runner 11.

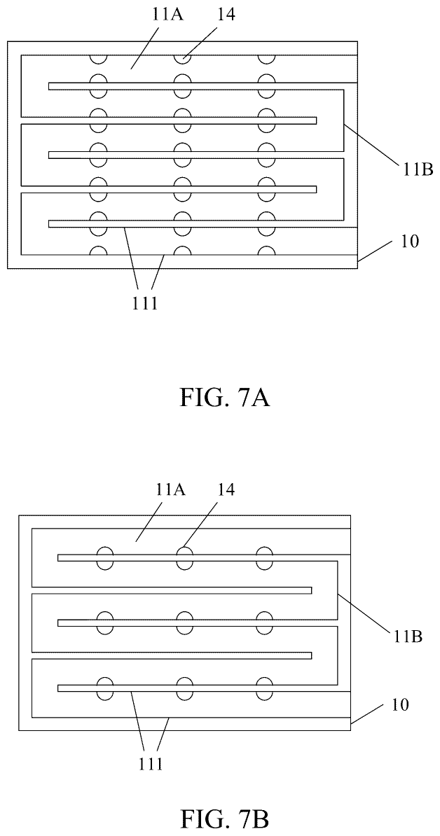

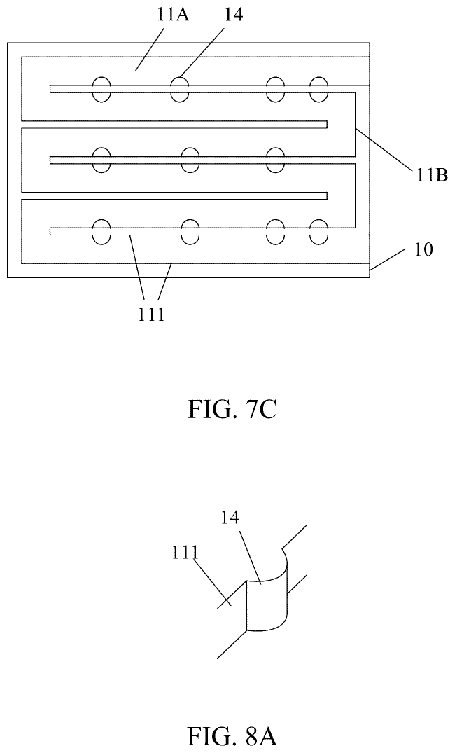

The runner 11 of the first plate 10 may be provided with one or more micro-rib structures 14. In most cases, the micro-rib structures 14 may be plural in number. FIG. 7A to FIG. 7C are schematic diagrams of several examples of the arrangement of the micro-rib structures in the runner in the embodiment of the present application.

In an example, as shown in FIG. 7A, the micro-rib structures 14 are arranged in an array in the straight segment 11A of the runner 11. In each straight segment 11A, two side surfaces 111 of the straight segment 11A are both provided with micro-rib structures 14.

In an example, as shown in FIG. 7B, the micro-rib structures 14 are arranged in an array in the straight segment 11A of the runner 11. In each straight segment 11A, one side surface 111 of the straight segment 11A is provided with micro-rib structures 14.

In an example, as shown in FIG. 7C, the micro-rib structures 14 are arranged in an irregular manner in the straight segment 11A of the runner 11. In each straight segment 11A, one side surface 111 of the straight segment 11A is provided with micro-rib structures 14. However, in each straight segment 11A, the number of micro-rib structures 14 and the spacing therebetween may be arbitrary.

It should be understood that the micro-rib structure 14 in the runner 11 may also be arranged in other ways, which is not specifically limited in the embodiments of the present application.

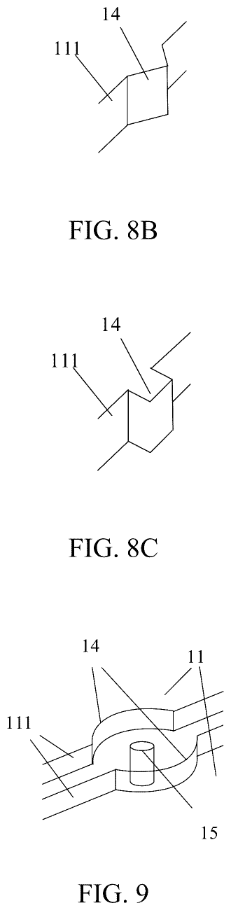

In an embodiment, the micro-rib structure 14 may be columnar. In this case, an extending direction of the micro-rib structure 14 may be perpendicular to the extending direction of the runner 11, and the length of the micro-rib structure 14 along the extending direction is the same as the height of the runner 11. In this way, a top surface of the micro-rib structure 14 may be flush with the first surface of the first plate 10. FIG. 8A to FIG. 8D are schematic diagrams of several examples of micro-rib structures in embodiments of the present application.

In an example, as shown in FIG. 8A, the micro-rib structure 14 may be semi-cylindrical.

In an example, as shown in FIG. 8B, the micro-rib structure 14 may be a triangular prism.

In an example, as shown in FIG. 8C, the micro-rib structure 14 may be a cuboid.

It should be understood that the micro-rib structure 14 may be other columnar structures, and may also have other shapes than columnar structures (for example, hemispheric and conical structures), which is not specifically limited in embodiments of the present application.

In the embodiment of the present application, the micro-rib structure 14 arranged on the side surface of the runner 11 can disturb the fluid flowing in the runner. Such disturbance can promote the heat exchange between the fluid and the heating device, so that the cooling device 1 has a stronger heat dissipation effect.

The cooling device 1 of the embodiments of the present application is configured for cooling the heating device. Then, the first plate 10 and/or the second plate 20 may be in contact with the heating device to achieve the heat exchange between the fluid in the runner 11 and the heating device. In order to make stable heat exchange between the cooling device 1 and the heating device, the heating device may be fixed to the cooling device 1.

In an embodiment, the heating device may be fixed to the cooling device 1 by bonding. In this case, an adhesive may be used to fix the heating device to the cooling device 1.

In an embodiment, the heating device may be fixed to the cooling device 1 by a screw. In this case, the cooling device 1 may be provided with a first mounting hole 15 and a second mounting hole 21 for the screw to pass through. The first mounting hole 15 is located in the first plate 10. The second mounting hole 21 is located in the second plate 20. The first mounting hole 15 and the second mounting hole 21 are aligned to each other. The positions of the first mounting hole 15 in the first plate 10 and the second mounting hole 21 in the second plate 20 may be determined according to the mounting position of the heating device.

The runner 11 of the first plate 10 is arranged to keep away from the first mounting hole 15 of the first plate 10. In an embodiment, the first mounting hole 15 may be located at the wall 113 of the runner 11. In an embodiment, the first mounting hole 15 may be located at the edge of the first plate 10.

In an embodiment, the micro-rib structure 14 may be arranged around the first mounting hole 15.

FIG. 9 is a perspective view of an example the micro-rib structure in the embodiment of the present application, the micro-rib structure being arranged around the first mounting hole. As shown in FIG. 9, the side surfaces 111, which are close to the first mounting hole 15, of the portions of the runner 11 located at two sides of the first mounting hole 15, are each provided with the micro-rib structure 14.

In the embodiment of the present application, the micro-rib structure 14 is arranged around the first mounting hole 15. Since the micro-rib structure 14 is arranged on the side surface 111 of the runner 11, the micro-rib structure 14 increases the thickness of the wall 113 of the runner 11 around the first mounting hole 15, compensates the cavity in the wall 113 caused by the first mounting hole 15, and ensures the thickness and sealing performance of the wall 113.

It should be noted that the first plate 10 and the second plate 20 of the cooling device 1 in the embodiments of the present application may be made of aluminum alloy or other metal material, which is not specifically limited in the embodiments of the present application.

Further, after obtaining the cooling device 1, the cooling device 1 may be subjected to subsequent processing. These processing include, but are not limited to, thread processing and surface processing.

After the manufacture of the cooling device 1 is completed, the cooling device 1 needs to be tested. The thickness of the wall 113 in the first plate 10 of the cooling device 1 and the test pressure for testing the cooling device 1, are all related to specific requirements.

The above-mentioned embodiments are merely used to illustrate the technical solutions of the present application, rather than limiting the present application. Although the present application has been described in detail with reference to the foregoing embodiments, those skilled in the art should understand that, modifications to the technical solutions described in the foregoing embodiments, or equivalent replacements to some technical features thereof, may be still made. These modifications or replacements do not make the essence of the corresponding technical solutions depart from the spirit and scope of the technical solutions of the embodiments of the present application, and shall all belong to the scope of protection of the present application.

What is claimed is:

1. A cooling device, comprising:
a first plate, wherein a first surface of the first plate is provided with a runner, the runner is configured for accommodating a fluid, and the runner has a zigzag shape; and
a second plate;
wherein the first surface of the first plate is in contact with the second plate.

2. The cooling device according to claim 1, wherein the first plate and the second plate are molded by cast-molding.

3. The cooling device according to claim 2, wherein the first plate and the second plate are integrated by brazing.

4. The cooling device according to claim 1, wherein the first plate and the second plate are integrated by brazing.

5. The cooling device according to claim 1, wherein the runner comprises a plurality of straight segments and a plurality of bent segments, the plurality of straight segments are arranged in parallel, and the plurality of straight segments are communicated with each other head to tail through the plurality of bent segments.

6. The cooling device according to claim 1, wherein a guide strip is disposed at a bent segment of the runner, and an extending direction of the guide strip is substantially consistent with an extending direction of the runner.

7. The cooling device according to claim 1, wherein an end portion of the runner is provided with an inlet-and-outlet port, and the inlet-and-outlet port is configured for the fluid to flow into and out of the runner;
wherein the inlet-and-outlet port is in communication with the runner at an obtuse angle.

8. The cooling device according to claim 1, wherein a side surface of the runner is provided with a micro-rib structure.

9. The cooling device according to claim 8, wherein the first plate is provided with a first mounting hole, the first mounting hole is configured for installing a heating device, and the micro-rib structure is arranged around the first mounting hole.
